(19) United States
(12) Patent Application Publication
(10) Pub. No.: US 2018/0132386 A1
(43) Pub. Date: May 10, 2018

(54) RADIATOR AND SERVER COOLING SYSTEM INCLUDING THE SAME

(71) Applicants: Inventec (Pudong) Technology Corporation, Shanghai (CN); INVENTEC CORPORATION, Taipei City (TW)

(72) Inventors: Kai-Yang TUNG, TAIPEI CITY (TW); Hung-Ju CHEN, TAIPEI CITY (TW)

(21) Appl. No.: 15/472,251

(22) Filed: Mar. 28, 2017

(30) Foreign Application Priority Data
Nov. 9, 2016 (CN) 201611035873.1

(51) Int. Cl. H05K 7/20; F28F 1/02; F28F 1/12

(52) U.S. Cl. CPC H05K 7/20772; F28F 1/02; H05K 7/20272; H05K 7/20263; F28F 1/126

(57) ABSTRACT

A radiator includes a first conducting pipe, a second conducting pipe, a plurality of radiating pipes, and a plurality of fins. The second conducting pipe is opposite to the first conducting pipe. The radiating pipes are parallel to each other and are in fluid communication with the first conducting pipe and the second conducting pipe. One of the radiating pipes has a vertical projection on an adjacent one of the radiating pipes. The vertical projection partially overlaps on the adjacent one of the radiating pipes. The fins are connected between adjacent two of the radiating pipes.

### CROSS-REFERENCE TO RELATED APPLICATION

This application claims priority to Chinese Applcation Serial Number 201611035873.1 filed Nov. 9, 2016, which is herein incorporated by reference.

### BACKGROUND

### Field of Invention

The present invention relates to a radiator. More particularly, the present invention relates to a server cooling system including the radiator.

### Description of Related Art

The use of cooling devices in electronic or mechanical applications common, especially for, such as, electronic devices, machine tools, or large machinery. The electronic devices or the machine tools tend to produce high temperatures during operation. The high temperatures often affect the performance of the electronic devices or the machine tools during operation, and may cause malfunctions in electronic devices or the machine tools, or damage to components therein. Therefore, important how the heat is discharged from the electronic devices or machine tools.

In the case of a computer or a server system a common cooling method is the use of a water cooling method or an air cooling method. An operating principle of a cooling water radiator is to bring the heat on the radiator away from the electronic devices or the machine tools by means of a fluid driven by the pump. Therefore, the cooling water radiator compared to an air cooling radiator has advantages, such as, quiet, stable cooling, and small dependence on an environment. However, the use of the water cooling radiator is often limited in the practical application because of a structural limitation of an arrangement, such as in electronic devices or the machine tools which may often limit an installation of the water cooling radiator therein. Furthermore, a location of vents in the water cooling radiator may reduce a heat dissipation of the fluid in different directions.

Relatively, a air cooling method is usually used to drive an air cooling fan to achieve a cooling effect. However, due to physical limitations, such as, a small specific heat of air, a heat dissipation efficiency provided from the air cooling method is generally poor and consumes considerable energy. In addition, sound of a fan motor itself and the wind produced from the air cooling method will produce considerable noise. More, specifically, tendency of electronic components in a computer system to be miniaturized today increases a heat density of the electronic components. Therefore, in material constraints and cost considerations, the air cooling method may not be able to provide a sufficient cooling capacity for the computer system.

Therefore, how to improve the aforementioned heat dissipation problem for the water cooling method or the air cooling method, or to improve the heat dissipation efficiency of the electronic devices is a problem that the person skilled in the art has been faced with.

### SUMMARY

The invention provides a radiator and a server cooling system including the radiator.

The present disclosure provides a server cooling system. The server cooling system includes a case and a radiator. The case has a bottom plate. The radiator is disposed in the case, and is located on the bottom plate. The radiator includes a first conducting pipe, a second conducting pipe, a plurality of radiating pipes, and a plurality of fins. The second conducting pipe is opposite to the first conducting pipe. The radiating pipes are parallel to each other and are in fluid communication with the first conducting pipe and the second conducting pipe. One of the radiating pipes of the radiator has a vertical projection on an adjacent one of the radiating pipes. The vertical projection partially overlaps on the adjacent one of the radiating pipes. The fins of the radiator are connected between adjacent two of the radiating pipes.

In some embodiments of the present disclosure, the fins of the radiator are respectively perpendicular to the bottom plate of the case.

In some embodiments of the present disclosure, at least one of the fins of the radiator is parallelogram.

In some embodiments of the present disclosure, the radiating pipes of the radiator are a plurality of flat cooling pipes respectively.

In some embodiments of the present disclosure, the flat cooling pipes are respectively perpendicular to the bottom plate of the case.

In some embodiments of the present disclosure, the fins of the radiator are respectively perpendicular to each of the flat cooling pipes.

In some embodiments of the present disclosure, the radiator further includes a connecting plate. The connecting plate is connected to an end of the first conducting pipe and an end of the second conducting pipe, and is located at a side of the flat cooling pipes. A virtual extension plane of any one of the flat cooling pipes of the radiator intersects a virtual extension plane of the connecting plate with a first angle.

In some embodiments of the present disclosure, the first conducting pipe of the radiator has a first surface and a second surface. The first surface is connected to the flat cooling pipes. The second surface is connected adjacent to the first surface. The second surface intersects each of the flat cooling pipes with a second angle.

In some embodiments of the present disclosure, the radiator further includes an inlet port, an outlet port, and a fluid. The inlet port is disposed on a side surface of the first conducting pipe. The outlet port is disposed on a side surface of the second conducting pipe. The fluid flows in the first conducting pipe, the second conducting pipe, and the radiating pipes through the inlet port and the outlet port.

In some embodiments of the present disclosure, the fluid includes water, oil, or refrigerant.

In some embodiments of the present disclosure, the sever cooling system includes a first insulating liquid. The first insulating liquid is at least filled in the case. A boil point of the first insulating liquid is in a range from about 40° C. (Celsius) to about 70° C. (Celsius).

In some embodiments of the present disclosure, the server cooling system includes a second insulating liquid. The second insulating liquid is at least filled in the case. A specific heat capacity of the second insulating liquid is substantially larger than 1012 J/(kg K) under a temperature in 25° C. (Celsius).

In the aforementioned configurations, the radiator of the present disclosure includes a first conducting pipe, a second conducting pipe, plural radiating pipes, and plural fins. One of the radiating pipes of the radiator has a vertical projection on an adjacent one of the radiating pipes. The vertical projection partially overlaps on the adjacent one of the radiating pipes. In other words, the radiating pipes which adjacent to each other are dislocated. Furthermore, because the flat cooling pipes and the fins are relatively perpendicular to the bottom plate of the case (that is, flat cooling pipes and the fins are parallel to a gravity direction), the radiating pipes will not obstruct the flow of vapor and condensate. Therefore, the condensed fluid can be directly dropped onto a lower tank of the case of the server cooling system by the influence of gravity rather than deposited on the radiator.

With such configuration, the radiating pipes can enhance the efficiency of the condensate recovery. Furthermore, the opening directions of the heat dissipating holes formed by the first conducting pipe, the second conducting pipe, and the flat cooling pipes are substantially parallel to gravity direction (that is, are aligned with the gravity direction), and thereby enabling the vapor to be easily in contact with the radiating pipes, thereby enhancing the condensing efficiency of the vapor and improving the cooling effect of the server cooling system.

It is to be understood that both the foregoing general description and the following detailed description are by examples and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is perspective view of a server cooling system according to some embodiments of the present disclosure;

FIG. 2 is a perspective view of a radiator according to some embodiments of the present disclosure;

FIG. 3 is a perspective view of a portion of at cooling pipes according to some embodiments of the present disclosure;

FIG. 4 is a perspective cross section view along line 4-4 in FIG. 2; and

FIG. 5 is side cross section view along line 4-4 in FIG. 2.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the singular forms “a,” “an” and “the” include plural referents unless the context clearly dictates otherwise. Therefore, reference to, for example, a gate stack includes aspects having two or more such gate stacks, unless the context clearly indicates otherwise. Reference throughout this specification to “one embodiment” or “an embodiment” means that a particular feature, structure, or characteristic described in connection with the embodiment is included in at least one embodiment of the present disclosure. Therefore, the appearances of the phrases “in one embodiment” or “in an embodiment” in various places throughout this specification are not necessarily all referring to the same embodiment. Further, the particular features, structures, or characteristics may be combined in any suitable manner in one or more embodiments. It should be appreciated that the following figures are not drawn to scale; rather, these figures are intended for illustration.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

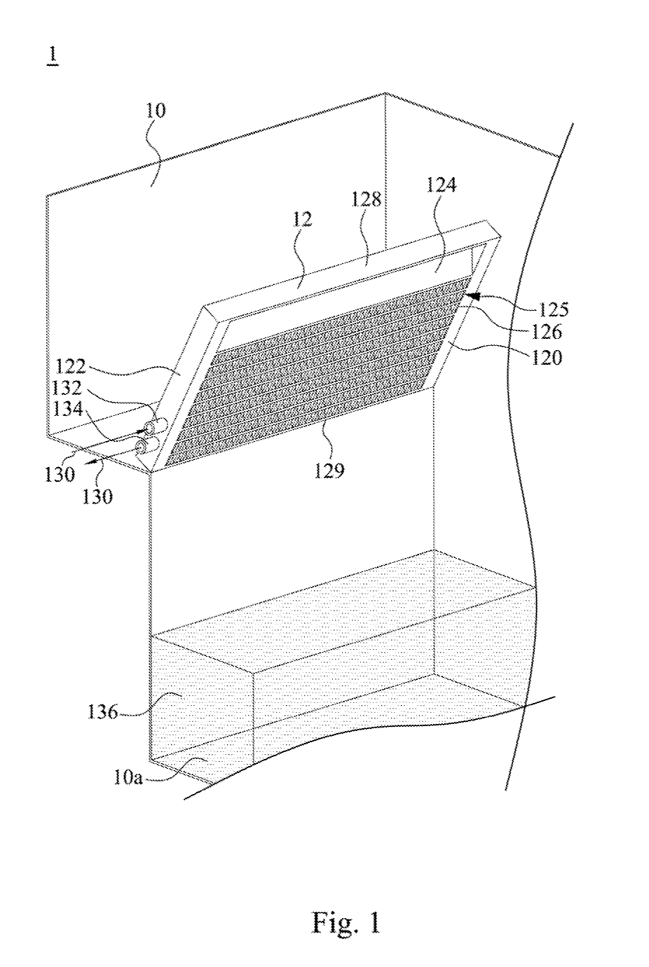

Reference is made to FIG. 1. FIG. 1 is a perspective view of a server cooling system 1 according to some embodiments of the present disclosure. As shown in FIG. 1, in the embodiment, the server cooling system 1 includes a case 10 (only depicted in partial) and a radiator 12. The case 10 includes a bottom plate 10a. The radiator 12 is disposed in the case 10 of the server cooling system 1, and includes a first conducting pipe 120, a second conducting pipe 122, a plurality of radiating pipes 124, and a plurality of fins 126. Furthermore, the server cooling system 1 includes an insulating liquid 136. The structure and function of the components and their relationships are described in detail hereinafter.

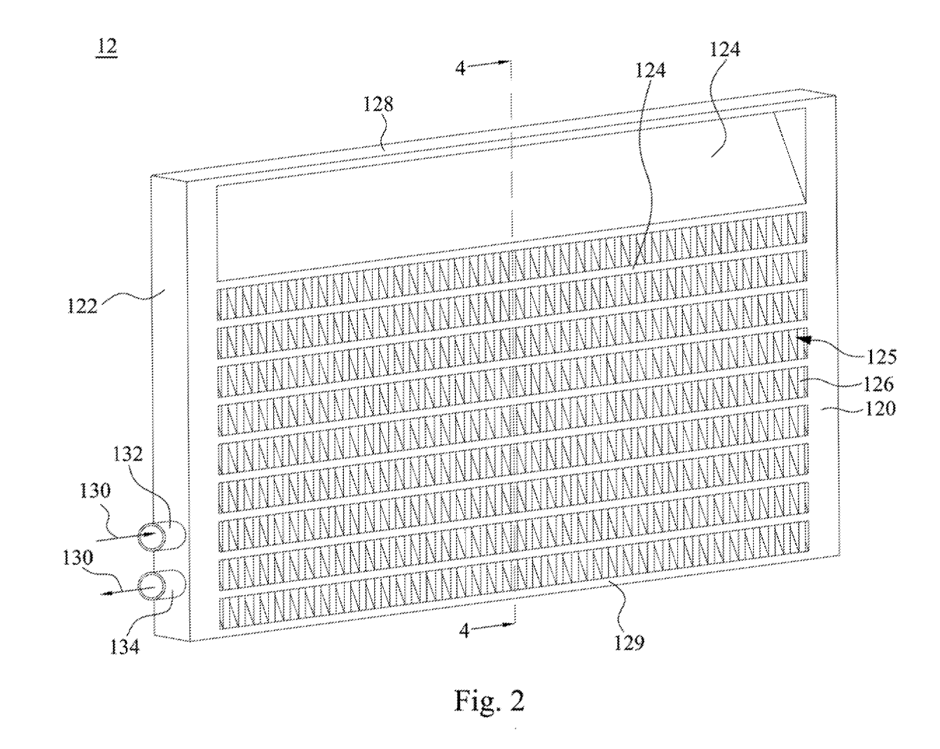

Reference is made to FIG. 2. FIG. 2 is a perspective view of a radiator 12 of the server cooling system 1 according to some embodiments of the present disclosure. In the embodiment, the radiator 12 is applied to cool the server cooling system 1 (see FIG. 1).

In FIG. 2, the insulating liquid 136 is filled in the case 10. Specifically, a boil point of the insulating liquid 136 is in a range from about 40° C. (Celsius) to about 70° C. (Celsius), and a specific heat capacity of the insulating liquid 136 is substantially larger than 1012 J/(kg-K) under a temperature in 25° C. (Celsius), but the present disclosure in not limited in this respect. In some embodiment, ail suitable insulating liquids that may cool the server cooling system 1 can be applied to the present disclosure. Furthermore, the server cooling system 1 is an immersion cooling system. That is, an electronic system (not shown, e.g. a server) is immersed in a fluid filled in the immersion cooling system. The fluid is nonconductive, and has a specific heat smaller than an air. The server cooling system 1 utilizes a flow caused by density or phase change of the fluid from a heat to remove the heat from the electronic system located in the server cooling system 1. With such configuration, the server cooling system 1 is able to omit devices (such as, a fan or a pump) that drive the fluid to flow for achieving a heat dissipation, and thereby enabling the server cooling system 1 reducing a power consumption for the electronic system by the insulating liquid 136 of the present disclosure.

In FIG. 2, the second conducting pipe 122 of the radiator 12 is disposed opposite to the first conducting pipe 120. The first conducting pipe 120 and the second conducting pipe 122 are square tubes. In some embodiments, the first conducting pipe 120 and the second conducting pipe 122 can be circular tubes. Furthermore, the first conducting pipe 120 and the second conducting pipe 122 located opposite two sides of the radiator 12 are used as a liquid tank to storage the liquid to help the subsequent heat dissipation.

In FIG. 2, the radiator 12 includes a connecting plate 128 and a connecting plate 129. The connecting plate 128 is connected to an end of the first conducting pipe 120 and an end of the second conducting pipe 122, and is located at a side of the radiating pipes 124. The connecting plate 129 is connected to another end of the first conducting pipe 120 and another end of the second conducting pipe 122, and is located at another side of the radiating pipes 124. The connecting plate 128 and the connecting plate 129 are used for increasing the strength of the radiator 12 on the structure. In the embodiment, the first conducting pipe 120, the second conducting pipe 122, the connecting plate 128, and the connecting plate 129 form a surrounding frame of the radiator 12. The radiating pipes 124 and the fins 126 are disposed in the surrounding frame.

In FIG. 2, the radiating pipes 124 of the radiator 12 are a plurality of flat cooling pipes respectively, and each has a flat appearance, and has two surfaces opposite to each other. The radiating pipes 124 are perpendicular to the bottom plate 10a of the case 10 (shown in FIG. 1). However, the appearance of the radiating pipes 124 of the present disclosure in not limited to the flat appearance. In other embodiments, an appearance of the radiating pipes 124 can be a circular tube or other suitable appearances. In the embodiment, the radiating pipes 124 are parallel to each other and are in fluid communication between the first conducting pipe 120 and the second conducting pipe 122. The first conducting pipe 120, the second conducting pipe 122, and the radiating pipes 124 surround to form a plurality of heat dissipating holes 125. Furthermore, the fins 126 and the radiating pipes 124 in the radiator 12 are configured to face toward a flowing direction of the fluid with the smallest projection area thereby reducing the obstruction of the fluid, whether the radiating pipes 124 and the fins 16 is in the form of that adjacent two of the flat cooling pipes clip the plural fins 126 or in the form of that each one of the radiating pipes 124 is rounded and each penetrates the plural fins 126.

Reference is made to FIG. 1. In FIG. 1, when the insulating liquid 136 absorbs heat of the electronic device (not shown) in the case 10, the insulating liquid 136 may produce a density or phase change and cause a flow of the insulating liquid 136 itself, and remove the heat form the electronic device. In other words, the insulating liquid 136 which absorbing the heat may be converted into vapor. As such, because the radiating pipes 124 of the radiator 12 are perpendicular to the bottom plate 10a of the case 10 (that is, the radiating pipes 124 are parallel to a gravity direction), the radiating pipes 124 will not obstruct a flow of vapor and condensate. Therefore, the condensed fluid can be directly dropped onto a lower tank of the case 10 of the server cooling system 1 by the influence of gravity rather than deposited on the radiator 12. With such configuration, the radiator 12 improves an efficiency of the condensate recovery. Furthermore, opening directions of the heat dissipating holes 125 formed by the first conducting pipe 120, the second conducting pipe 122, and the radiating pipes 124 are parallel to the gravity direction. That is, the opening directions of the heat dissipating holes 125 are substantially aligned with the gravity direction, thereby enabling the vapor to be easily in contact with the radiating pipes 124, and thereby enhancing a condensing efficiency of the vapor and improving a cooling effect of the server cooling system 1.

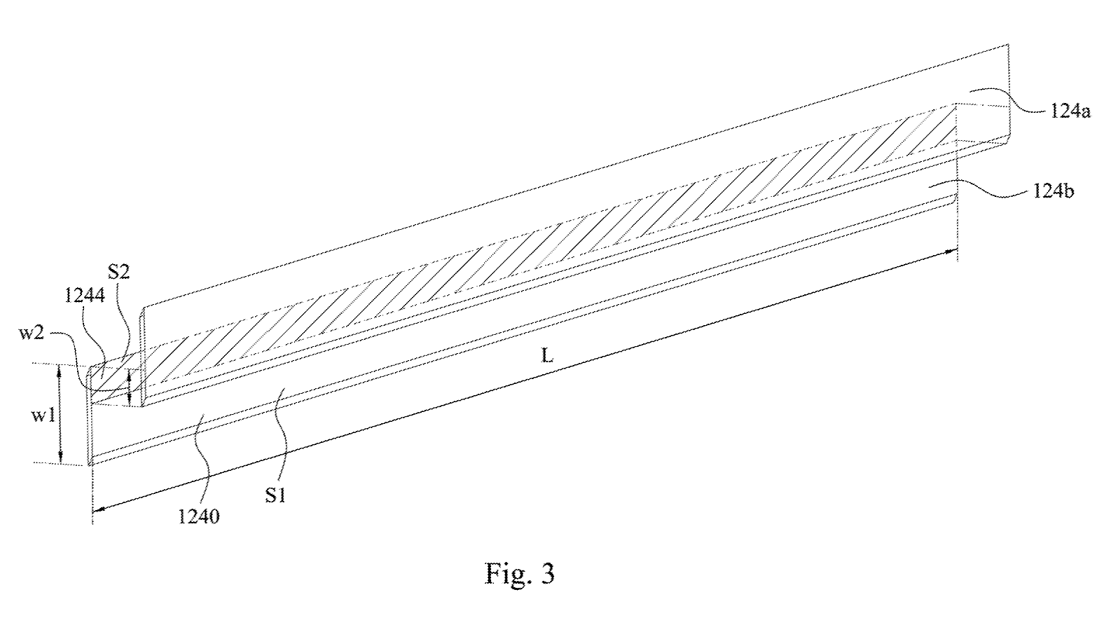

Reference is made to FIG. 3. FIG. 3 is a perspective view of a portion of the flat cooling pipes 124 (two are depicted) according to some embodiments of the present disclosure. Furthermore, the fins 126 disposed between the radiating pipes 124 are omitted to illustrate in FIG. 3 for more detailed describing the embodiment. As shown in FIG. 3, in the embodiment, one of the radiating pipes 124 has a vertical projection 1244 on an adjacent one of the radiating pipes 124. The vertical projection 1244 partially overlaps the adjacent one of the radiating pipes 124.

For example, in FIG. 3, a third surface 1240 of the radiating pipe 124b has a length L and a width W1. The radiating pipe 124a has a length L and a width W1. The radiating pipe 124a has a vertical projection 1244 on the radiating pipe 124b. The vertical projection 1244 has a length L and a width W2 and the width W2 is smaller than the width W1 of the radiating pipe 124b. The vertical projection 1244 of the radiating pipe 124a partially overlaps the radiating pipe 124b. In other words, an area S2 of the vertical projection 1244 is smaller than an area S1 of the third surface 1240 of the radiating pipe 124b.

In other words, the radiating pipes 124 are parallel to each other, and which adjacent to each other are dislocated. Therefore, it is possible to change misalignment relationship between any adjacent two of the radiating pipes 124 according to the requirements of the radiator 12 for practical use so as to appropriately arrange the radiator 12 on the apparatus which is needed to be heat dissipated for achieving the heat dissipation required for practical use.

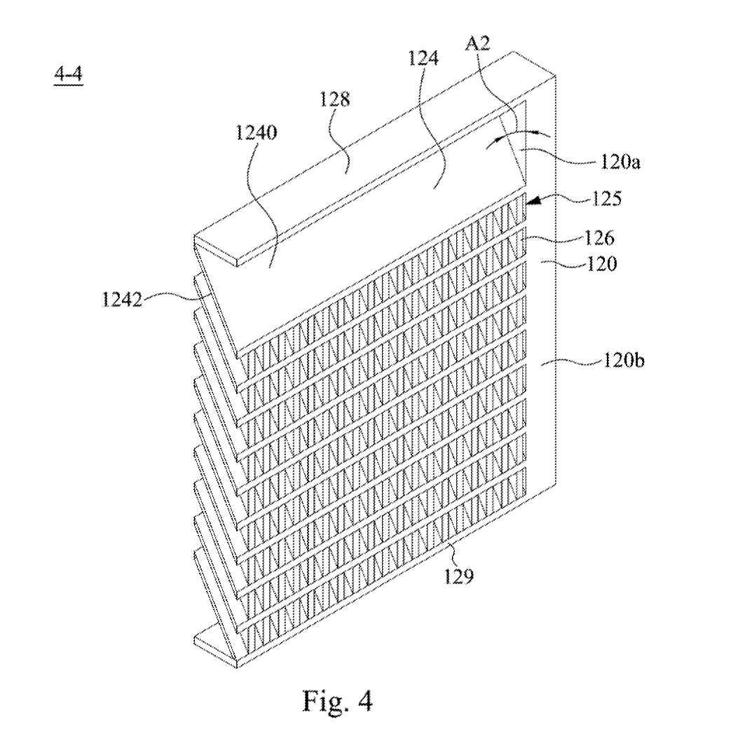

Reference is made to FIG. 4, FIG. 4 is a perspective cross section view along line 4-4 in FIG. 2. In FIG. 2, a plurality of fins 126 of the radiator 12 is connected between adjacent two of the radiating pipes 124, and is perpendicular to the radiating pipes 124 and the bottom plate 10a of the case 10 (shown in FIG. 1). In the embodiment, a profile of each of the fins 126 is a parallelogram, but the present disclosure in not limited in this respect. In other embodiments, a profile of each of the fins can be any other suitable shapes.

With such configuration, the radiating pipes 124 of the radiator 12 are perpendicular to the bottom plate 10a of the case 10, and the fins 126 of the radiator 12 are also perpendicular to the bottom plate 10a. As such, the radiating pipes 124 and the fins 126 may not obstruct the flow of the vapor, and disposing the fins 126 between adjacent two of the radiating pipes 124 may increase a contact area of the vapor with the radiator 12, thereby enhancing the condensing efficiency of the vapor, improving the cooling effect of the server cooling system 1, and improving the efficiency of the condensate recovery.

Specifically, in FIG. 4, the first conducting pipe 120 of the radiator 12 has a first surface 120a and a second surface 120b. The first surface 120a faces toward the radiating pipes 124, and is connected to the radiating pipes 124. The second surface 120b is connected adjacent to the first surface 120a. Each of the radiating pipes 124 has a third surface 1240 and a fourth surface 1242 opposite to the third surface 1240. The third surface 1240 and the fourth surface 1242 are connected between the first conducting pipe 120 and the second conducting pipe 122 (shown in FIG. 2). The third surface 1240 substantially faces the connecting plate 128, and the fourth surface 1242 substantially faces the connecting plate 129. The second surface 120b intersects the third surface 1240 of each of the radiating pipes 124 with a second angle A2.

Therefore, because an angle between the connecting plate 129 of he radiator 12 and the bottom plate 10a of the case 10 (shown in FIG. 1) can be adjusted to be the same as the second angle A2, such configuration can make the radiating pipes 124 be relatively perpendicular to the bottom plate 10a of the case 10, thereby enabling the radiator 12 to enhance the condensing efficiency of the vapor, improve the cooling effect of the server cooling system 1, and improve the efficiency of the condensate recovery.

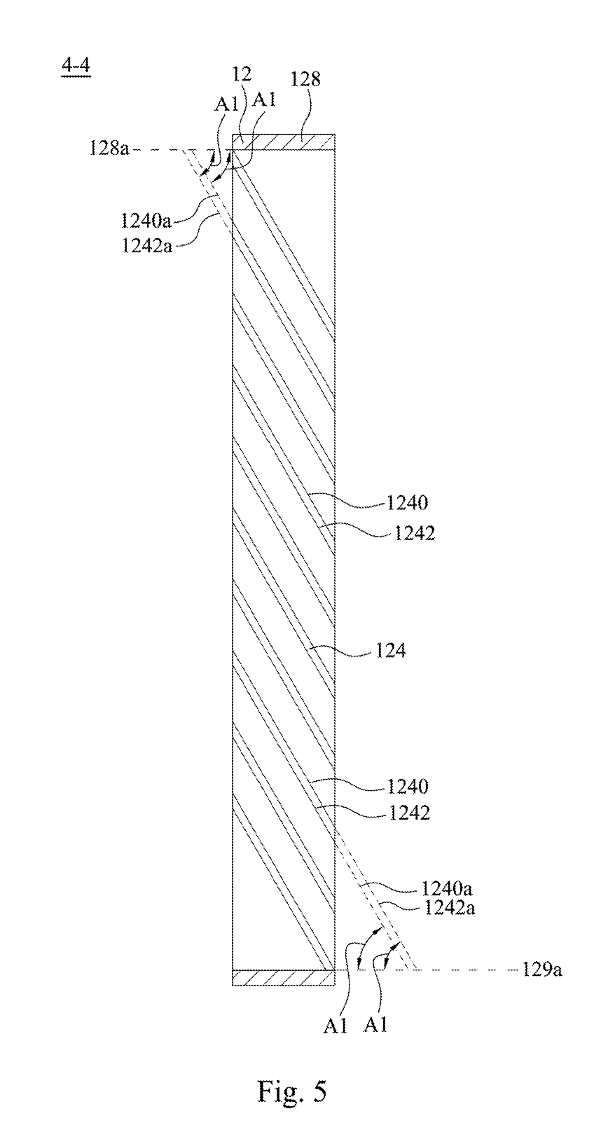

Reference is made to FIG. 5. FIG. 5 is a side cross section view along line 4-4 in FIG. 2. In FIG. 5, the third and fourth surfaces 1240 and 1242 of any one of the radiating pipes 124 of the radiator 12 respectively have virtual extension planes 1240a and 1242a. The connecting plates 128 and 129 respectively have virtual extension planes 128a and 129a. The virtual extension plane 1240a of any one of the radiating pipes 124 intersects the virtual extension planes 128a and 129a of the connecting plates 128 and 129 with first angles A1 respectively, and the virtual extension plane 1240b of any one of the radiating pipes 124 intersects the virtual extension planes 128a and 129a of the connecting plates 128 and 129 with a first angle A1 respectively.

Therefore, because an angle between the connecting plate 128 (or the connecting plate 129) of the radiator 12 and the bottom plate 10a of the case 10 (shown in FIG. 1) can be adjusted to be another angle, and said another angle is added to be substantially 90 degrees with the first angle A1, such configuration can make the radiating pipes 124 are relatively perpendicular to the bottom plate 10a of the case 10, thereby enabling the radiator 12 to enhance the condensing efficiency of the vapor, improve the cooling effect of the server cooling system 1, and improve the efficiency of the condensate recovery.

Reference is made to FIG. 1. In FIG. 1, the radiator 12 further includes an inlet port 132 and an outlet port. The inlet 132 and outlet port 134 are disposed on a surface of the second conducting pipe 122. In other embodiments, the inlet 132 and outlet port 134 can be deposited on a surface of the first conducting pipe 120. In the embodiment, the radiator 12 further includes a fluid 130. The fluid 130 flowing in the first conducting pipe 120, the second conducting pipe 122, and the radiating pipes 124 through the inlet port 132 and the outlet port 134. The fluid 130 can include water, oil, or refrigerant.

With such configuration, the server cooling system 1 can circulate the heat and take away the heat from the server cooling system 1 through the radiator 12 by utilizing the fluid 130 in the radiator 12 under the drive of the pump. However, in other embodiments, the server cooling system 1 may utilize a pressure difference of the fluid 130 between the inlet port 132 and the outlet port 134 to drive circulation of the fluid 130 without the pump to drive circulation of the fluid 130. In addition, the vapor in the server cooling system 1 can be condensed by the circulation of the aforementioned fluid 130 and can provide cooling of the components in the server cooling system 1.

According to the foregoing recitations of the embodiments of the disclosure, it can be seen that the radiator of the present disclosure includes a first conducting pipe, a second conducting pipe, plural radiating pipes, and plural fins. One of the radiating pipes of the radiator has a vertical projection on an adjacent one of the radiating pipes. The vertical projection partially overlaps on the adjacent one of the radiating pipes. In other words, the radiating pipes which adjacent to each other are dislocated. Furthermore, because the flat cooling pipes and the fins are relatively perpendicular to the bottom plate of the case (that is, flat cooling pipes and the fins are parallel to a gravity direction), the radiating pipes will not obstruct the flow of vapor and condensate. Therefore, the condensed fluid can be directly dropped onto a lower tank of the case of the server cooling system by the influence of gravity rather than deposited on the radiator.

With such configuration, the radiating pipes can enhance the efficiency of the condensate recovery. Furthermore, the opening directions of the heat dissipating holes formed by the first conducting pipe, the second conducting pipe, and the flat cooling pipes are substantially parallel to gravity direction (that is, are aligned with the gravity direction), and thereby enabling the vapor to be, easily in contact with the radiating pipes, thereby enhancing the condensing efficiency of the vapor and improving the cooling effect of the server cooling system.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A radiator, comprising:
a first conducting pipe;
a second conducting pipe disposed opposite to the first conducting pipe;
a plurality of radiating pipes parallel to each other and in fluid communication with the first conducting pipe and the second conducting pipe, wherein one of the radiating pipes has a vertical projection on an adjacent one of the radiating pipes, and the vertical projection partially overlaps on the adjacent one of the radiating pipes; and
a plurality of fins each connected between adjacent two of the radiating pipes.

2. The radiator of claim 1, wherein the radiating pipes are a plurality of flat cooling pipes respectively.

3. The radiator of claim 2, further comprising:
a connecting plate connected to an end of the first conducting pipe and an end of the second conducting pipe, and located at a side of the flat cooling pipes, wherein a virtual extension plane of any one of the flat cooling pipes intersects a virtual extension plane of the connecting plate with a first angle.

4. The radiator of claim 2, wherein the first conducting pipe has a first surface and a second surface, the first surface is connected to the flat cooling pipes, and the second surface is connected adjacent to the first surface, wherein the second surface intersects each of the flat cooling pipes with a second angle.

5. The radiator of claim 1, further comprising:
an inlet port disposed on a side surface of the first conducting pipe;
an outlet port disposed on a side surface of the second conducting pipe; and
a fluid flowing in the first conducting pipe, the second conducting pipe, and the radiating pipes through the inlet port and the outlet port.

6. A server cooling system, comprising:
a case having a bottom plate; and
a radiator disposed in the case, and located on the bottom plate, and the radiator comprising:
a first conducting pipe;
a second conducting pipe disposed opposite to the first conducting pipe;
a plurality of radiating pipes parallel to each other and in fluid c communication with the first conducting pipe and the second conducting pipe, wherein one of the radiating pipes has a vertical projection on an adjacent one of the radiating pipes, and the vertical projection partially overlaps on the adjacent one of the radiating pipes; and
a plurality of fins each connected between adjacent two of the radiating pipes.

7. The server cooling system of claim 6, wherein the radiating pipes are a plurality of flat cooling pipes respectively.

8. The server cooling system of claim 7 further comprising:
a connecting plate connected to an end of the first conducting pipe and an end of the second conducting pipe, and located at a side of the flat cooling pipes, wherein a virtual extension plane of any one of the flat cooling pipes intersects a virtual extension, plane of the connecting plate with a first angle.

9. The server cooling system of claim 7, wherein the first conducting pipe has a first surface and a second surface, the first surface is connected to the flat cooling pipes, and the second surface is connected adjacent to the first surface, wherein the second surface intersects each of the flat cooling pipes with a second angle.

10. The server cooling system of claim 6, further comprising
an inlet port disposed on a side surface of the first conducting pipe,
an outlet port disposed on a side surface of the second conducting pipe, and
a fluid flowing in the first conducting pipe, the second conducting pipe, and the radiating pipes through the inlet port and the outlet port.
